(19) United States
(12) Patent Application Publication
(10) Pub. No.: US 2013/0000968 A1
(43) Pub. Date: Jan. 3, 2013

(54) 1-Layer Interposer Substrate With Through-Substrate Posts

(75) Inventors: Sam Ziqun Zhao, Irvine, CA (US); Rezaur Rahman Khan, Rancho Santa Margarita, CA (US); Raymond Kwok Cheung Tsang, Irvine, CA (US)

(73) Assignee: Broadcom Corporation, Irvine, CA (US)

(21) Appl. No.: 13/173,689

(22) Filed: Jun. 30, 2011

(51) Int. Cl. H05K 1/11; H05K 3/42; H05K 3/02

(52) U.S. Cl. 174/266; 29/846; 29/852

(57) ABSTRACT

A method of manufacturing a printed circuit board is disclosed. A conductive metal layer is formed on a first surface of a dielectric substrate. One or more vias are formed through the substrate. A conductive metal layer is formed on the first surface of the substrate and is patterned to form conductive traces on the first surface of the substrate. A plating mask is formed on the second surface of the substrate. One or more openings are formed in the plating mask to correspond to the location of the via(s). Conductive metal is deposited in the via(s) sufficient to substantially fill the via(s) and make contact with the conductive metal layer on the first surface and substantially to the level of the plating mask. The plating mask is removed from the substrate such that one or more conductive posts extend outwardly from the second surface of the substrate.

### BACKGROUND OF THE INVENTION

1. Field of the Invention

The invention relates to the field of integrated circuit (IC) device substrate technology.

2. Background of the Disclosure

Integrated circuit (IC) packages include printed circuit boards (PCBs) on which electronic components are mounted. A printed circuit board, or PCB, is used to mechanically support and electrically connect electronic components using conductive pathways, tracks or signal traces etched from copper sheets laminated onto a substantially non-conductive substrate. It is also referred to as printed wiring board (PWB) or etched wiring board. A PCB populated with electronic components is a printed circuit assembly (PCA), also known as a printed circuit board assembly (PCBA).

Conducting layers are typically made of thin copper foil. Insulating layers of dielectric material are typically laminated together with epoxy resin. The board is typically coated with a solder mask that is typically, but not necessarily, green in color. There are quite a few different dielectrics that can be chosen to provide different insulating values depending on the requirements of the circuit. Some of these dielectrics are polytetrafluoroethylene (Teflon), BT, FR-4, FR-1, CEM-1 or CEM-3. Thermal expansion is an important consideration especially with ball grid array (BGA) and naked die technologies, and glass fiber offers good dimensional stability.

BT, which is mainly B (Bismaleimide) and T (Triazine) formed as a resin by polymerization, and FR-4, made of woven fiberglass cloth with an epoxy resin binder that is flame resistant, are the most common materials used today as substrates for PCBs. The board with copper on it is called “copper-clad laminate”. Copper foil thickness can be specified in ounces per square foot or micrometres. One ounce per square foot is 1.344 mils or 34 micrometres.

Multiple conductive layers of a PCB are connected by vias. A via is a vertical electrical connection between different layers of conductors in a printed circuit board. A via includes two pads, in corresponding positions on different layers of the board, that are electrically connected by a hole through the board. Conductive posts may be formed in the vias to connect one part of a PCBA with other conductors, such as solder balls or contact pads.

Provisional application 61/448,880, filed Mar. 3, 2011, in the names of Rezaur R. Khan and Sam Z. Zhao discloses methods of manufacturing IC packages that provide vertical package interconnection to form PCBAs. The disclosure of the '880 application is incorporated herein by reference as if set forth in full herein.

PCB substrates are typically formed as one layer or two layer substrates. That is, the substrates either have one conductive layer (one layer substrate) or two conductive layers (two layer substrate), one on each of opposite (e.g., top and bottom) surfaces of the substrate. Typically, one layer substrates, whether they are flexible or rigid, have lower manufacturing costs than do two layer substrates. In conventional PCB manufacturing, contact terminals are plated on top of the conductive layer.

### BRIEF SUMMARY

A method of manufacturing a printed circuit board is disclosed. A conductive metal layer is formed on a first surface of a dielectric substrate. One or more vias are formed through the substrate. A conductive metal layer is formed on the first surface of the substrate and is patterned to form conductive traces on the first surface of the substrate. A plating mask is formed on the second surface of the substrate. One or more openings are formed in the plating mask to correspond to the location of the via(s). Conductive metal is deposited in the via(s) sufficient to substantially fill the via(s) and make contact with the conductive metal layer on the first surface and substantially to the level of the plating mask. The plating mask is removed from the substrate such that one or more conductive posts extend outwardly from the second surface of the substrate.

These and other objects, advantages and features will become readily apparent in view of the following detailed description of the invention. Note that the Summary and Abstract sections may set forth one or more, but not all exemplary embodiments of the present invention as contemplated by the inventor(s).

### BRIEF DESCRIPTION OF THE DRAWINGS/FIGURES

The accompanying drawings, which are incorporated herein and form a part of the specification, illustrate the present invention and, together with the description, further serve to explain the principles of the invention and to enable a person skilled in the pertinent art to make and use the invention. In the drawings, like reference numbers may indicate identical or functionally similar elements. The drawing in which an element first appears is generally indicated by the left-most digit in the corresponding reference number.

FIG. 1 shows an embodiment of a printed circuit board formed according to the steps described herein.

FIGS. 2(a)-(g) collectively show the steps of a first method of making a printed circuit board.

FIGS. 3(a)-(g) collectively show the steps of a second method of making a printed circuit board.

FIGS. 4(a)-(h) collectively show the steps of a third method of making a printed circuit board.

FIG. 5 shows a printed circuit board formed according to the steps described herein with an adhesive layer.

FIG. 6 shows a printed circuit board mounted to a bottom substrate assembly.

FIG. 7 shows a cross-sectional view of a copper post formed according to the steps described herein.

### DETAILED DESCRIPTION OF EMBODIMENTS

It is noted that references in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described.

Furthermore, it should be understood that spatial descriptions (e.g., “above”, “below”, “left,” “right,” “up”, “down”, “top”, “bottom”, etc.) used herein are for purposes of illustration only, and that practical implementations of the structures described herein can be spatially arranged in any orientation or manner.

The present invention is directed primarily to a method of making a low cost substrate or interposer or PCB (the terms “substrate,” “interposer,” and “printed circuit board” or “PCB” are used interchangeably). Embodiments of the invention leverage the existing infrastructure of the process for manufacturing PCBs. Embodiments incorporating the inventive concepts result in a PCB having certain features not normally available with low cost manufacturing processes.

A substrate is a type of PCB that is typically used as a chip carrier. Traditional rigid substrate technology uses a well-known BT dielectric material as part of the substrate, which is mainly B (Bismaleimide) and T (Triazine) formed as a resin by polymerization. Other well-known dielectric materials, such as FR-4 (a glass reinforced epoxy laminate), and silicon can also be used. PCBs are typically one layer or two layer substrates. Substrates made of materials such as BT and FR-4 are generally rigid, with little or no flexibility.

A second type of dielectric material is a tape. Typically the tape is a plastic material, such as polyimide. The material can be made very thin, and is flexible. The process of manufacturing PCBs using tape is different from the process used to make BT or FR-4 PCBs.

In a one layer PCB or interposer, there is one conductive layer; in a two layer PCB or interposer, there are two conductive layers. In a one layer PCB, all of the traces (the conductive leads running between the electrical components on the PCB) are located in one plane. In a two layer PCB, there are two conductive layers separated by a dielectric layer. The traces on each layer can have different patterns. Typically, the two layers are electrically connected by conductive vias. It will be apparent to those skilled in the relevant art that more than two layer PCBs can be made.

Manufacturing costs are directly related to the number of conductive layers that are provided on a PCB. In general, the more layers there are, the higher the manufacturing cost will be. In addition, the yield will drop as layers are added, due to the fact that one or more layers can develop problems during the manufacturing process that makes the final PCB unusable. There is a dramatic cost difference between one layer tape PCBs and two layer PCBs. The cost of two layer tape PCBs is substantially higher than one layer tape PCBs.

Currently, substrates are being manufactured with conductive posts or pillars to interconnect the layers and to connect components mounted on the substrate. These posts are typically copper or gold, both of which are good conductors. A metal foil, such as copper or gold, is laminated on the surface of the dielectric substrate. The metal foil is then patterned into the circuit traces by, for example, a chemical or optical lithography etching process. Pads or bumps are formed by building up or plating the foil at certain points on the traces to provide “bumps” or contact points. This is called an “additive” process. This process is well known. Another well-known process for forming bumps is by etching away the metal foil except where the bumps are to be formed. This is called a “subtractive” process. In both the additive and subtractive processes, the bumps are formed on the top of the substrate. The bumps must be on the same side of the conductor. However, if the bumps are on the same side of the conductor and it is desired to have an interconnect on the other side of the substrate, then it is necessary to have at least two layers. This then leads to increased manufacturing costs.

A feature of the present invention is the use of one layer technology and having the conductive metal posts formed on the opposite side of the substrate from the conductive layer. In the discussion below, the term copper post, copper layer or copper trace is used for convenience. However, it will be understood by those skilled in the relevant arts that any suitable conductive material that may be deposited, grown, etched or otherwise patterned to form conductive traces and/or posts on the substrate can be used. Such materials include, but are not limited to, gold, silver, tin, aluminum, etc.

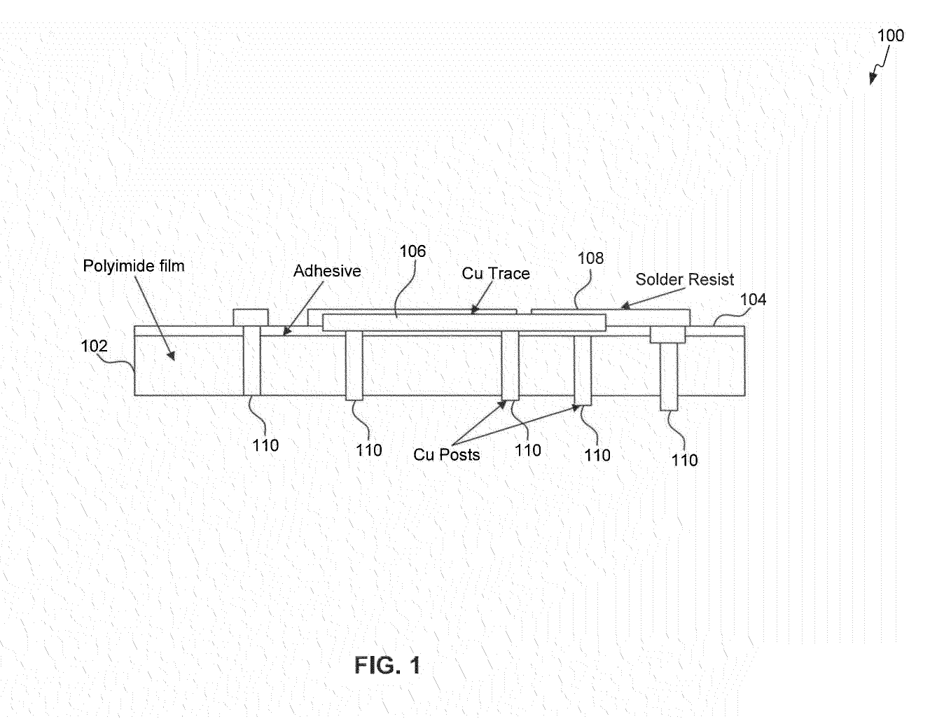

FIG. 1 shows an interposer 100 with through-substrate posts.

Interposer 100 has a dielectric 102, which may be rigid, such as BT or FR-4, or flexible, such as a polyimide film. On one (e.g., a top) surface of dielectric 102 is an adhesive layer 104. Adhesive layer 104 provides a base onto which a metal foil layer 106, such as copper, is attached or formed (e.g., lamination, grown, deposited, etc). A solder resist layer 108 is laid down on top of metal foil layer 106. Metal foil layer 106 is patterned into traces. Thus far a typical PCB has been described.

An embodiment incorporating features of the present invention will now be described. Conductive metal posts 110 (e.g., copper) are formed (e.g., grown, deposited, etc.) through dielectric 102 from the bottom of dielectric 102 to the top surface of dielectric 102 where they make contact with the traces of metal foil layer 106.

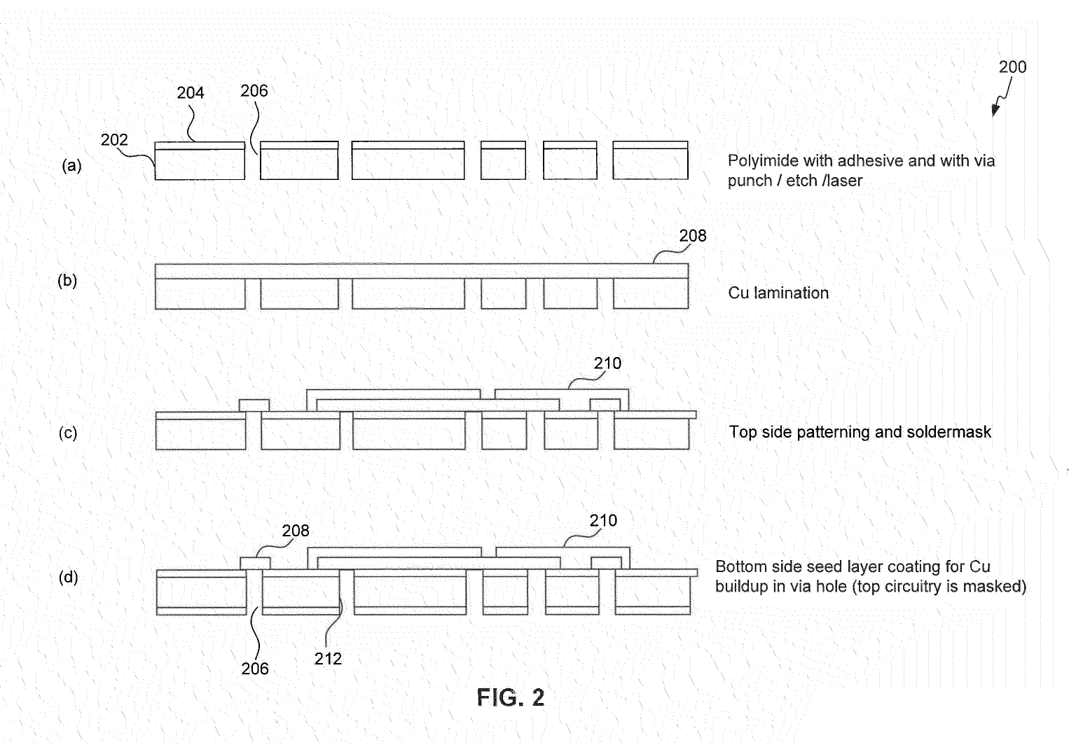

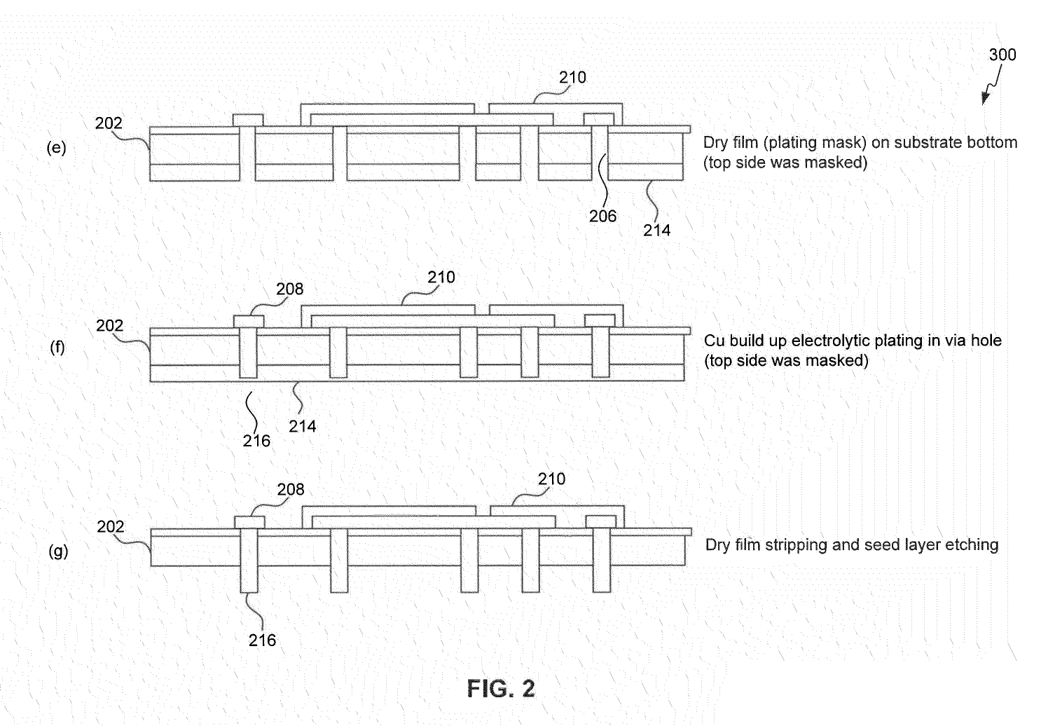

FIGS. 2(a)-(h) show a first example of a process for manufacturing a one layer interposer 200 with copper posts formed through a dielectric 202. At a first step, an adhesive layer 204 is added to one side of dielectric 202. One or more vias or through holes 206 are formed through dielectric 202 and adhesive layer 204 by, for example, a punch, by etching, or by a laser (FIG. 2(a)). After forming vias 206, a copper layer 208 is laminated onto adhesive layer 204 (FIG. 2(b)). Copper layer 208 is then patterned to form conductive traces on the top surface of dielectric 202 and a solder mask 210 is laid down on top of parts of copper layer 208 and adhesive layer 204 (FIG. 2(c)). The methods for forming vias and conductive traces on a single layer substrate are well known to those skilled in the relevant arts.

FIG. 2(d) shows a first step of a feature of one embodiment of the present invention. A bottom seed layer coating 212 to permit copper buildup in via hole 206 is deposited on the bottom of dielectric 202 and on the inside of vias 206. At this stage, the top surface circuitry of interposer 200 is completely masked (not shown). Seed layer 212 can be deposited by wet or dry chemical processes, such as sputtering. Seed layer 212 is a very thin layer, typically only a few microns thick. Seed layer 212 is too thin to be used as an interconnect layer on the PCB. If current is passed through seed layer 212 it would burn away, thus acting as a fuse.

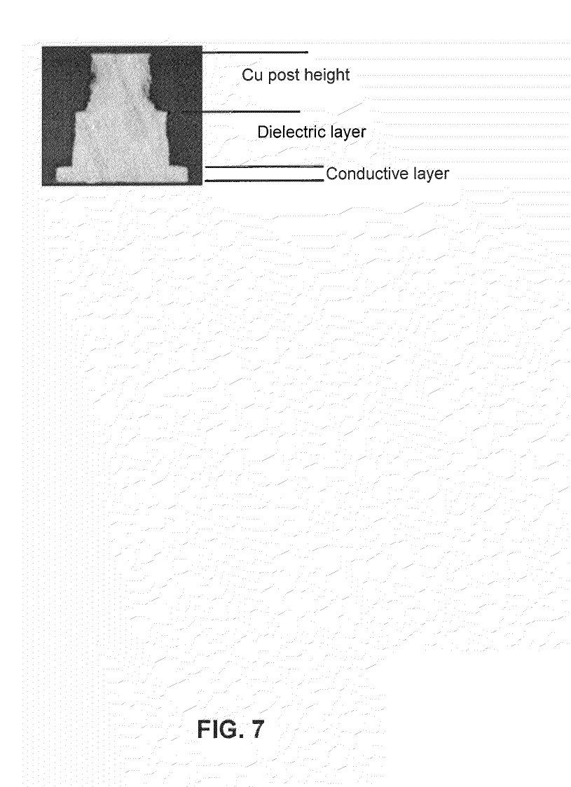

FIG. 2(e) shows the next step of the process. In this step, a dry film plating mask 214 is formed on seed layer 212 on the bottom surface of dielectric 202. Via holes 206 are exposed through plating mask 214. Typically, the holes formed in plating mask 214 are not exactly aligned with via holes 206. This is because plating mask 214 is formed using photolithography techniques and the holes in plating mask 214 are etched in mask 214. The effects of this slight misalignment are discussed below with reference to FIG. 7.

Next, as shown in FIG. 2(f), copper is deposited in via holes 206 and built up to form posts 216. Posts 216 extend completely through via holes 206 to contact copper layer 208 on the top surface of dielectric 202. Copper posts 216 are deposited sufficiently, such as by electrolytic plating, so that they contact copper layer 208 on the top surface of dielectric 202 and extend outwardly from the bottom surface of dielectric 202 through plating mask 214 to a required height.

FIG. 2(g) shows the next step of the process. Plating mask 214 is stripped off to expose copper posts 216 extending from the bottom surface of dielectric 202 and seed layer 212. At this stage, posts 216 are electrically shorted through conductive seed layer 212. In the final step of the process, seed layer 212 is removed by a flash etching or equivalent process to leave the bottom surface of dielectric 202 exposed and copper posts 216 extending outwardly from the bottom surface of dielectric 202. Flash etching is a chemical process used to remove a very thin layer of copper. The copper posts are isolated from each other on the bottom side of the interposer after etching away the seed layer.

In a variation of the above-described process, the steps of patterning copper layer 208 into conductive traces and applying solder mask 210 can be performed after the steps of removing plating mask 214 and seed layer 212.

In a further variation of the above-described process, the step of coating the bottom surface of dielectric 202 with seed layer 212 can be eliminated. In this variation, dry film plating mask 214 is formed directly on the bottom surface of dielectric 202. Openings are made in dry film mask 202 that aligns with the via holes 206 in dielectric 202. Cu posts 216 are plated through the via holes 206 and built from the bottom of dielectric 202. In this variation, the steps of patterning copper layer 208 into conductive traces and applying solder mask 210 to the top surface of dielectric 202 can be performed before plating mask 214 is formed on the bottom surface of dielectric 202 and copper posts 216 are built up. Alternatively, the copper layer 208 patterning and solder mask 210 formation can be done after plating mask 214 is removed. FIG. 7 shows a cross section of a 1-layer Cu post 216 using this variation.

This embodiment, in its several variations, is based on the idea of using a single metal layer process. Additional embodiments, discussed below, incorporating features of the present invention are based on the concept of using two or more metal layers.

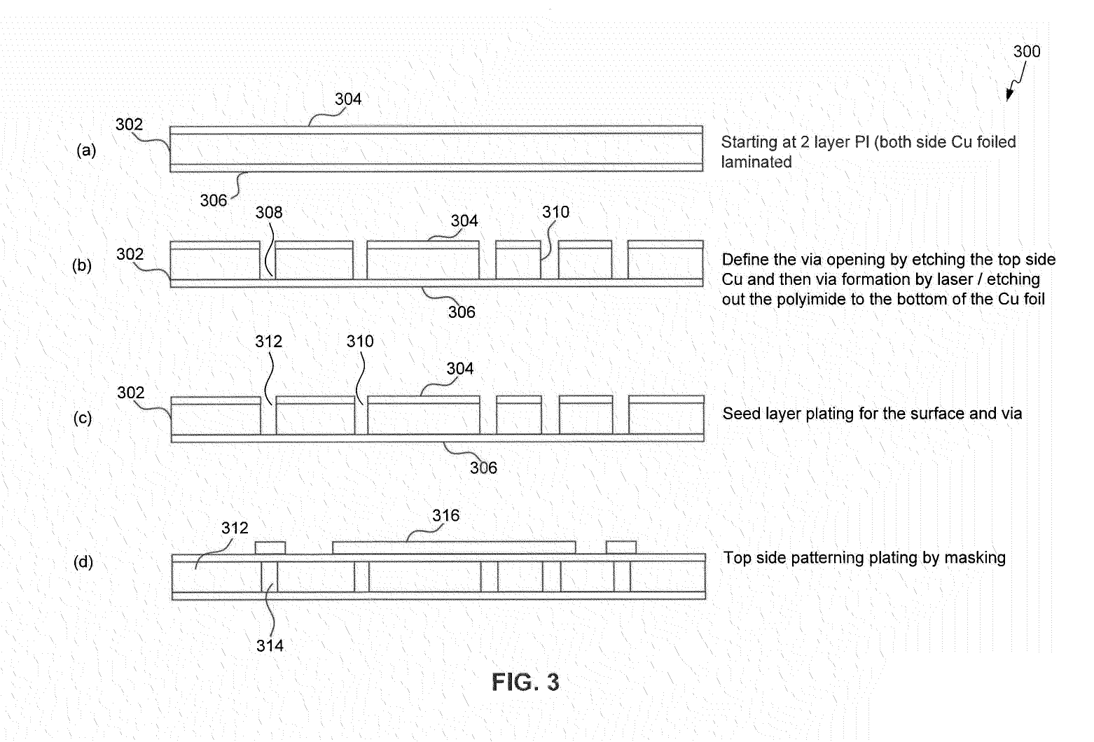

FIGS. 3(a)-(g) show a second embodiment incorporating features of the present invention. This embodiment begins with a dielectric 302 having a first copper foil 304 laminated on the top surface of dielectric 302 and a second copper foil 306 laminated on the bottom surface of dielectric 302. In this embodiment, foil layers 304 and 306 are laminated directly onto the surfaces of dielectric 302 (FIG. 3(a)). Alternatively, one or more of conductor foil layers 304 and 306 can be formed on an adhesive layer that is formed directly on dielectric 302. Via openings 308 are formed in first copper layer 304 by chemical etching or similar process to expose the substrate surface in the etched regions. Vias 310 are then formed in dielectric 302 by chemical or laser etching (or equivalent techniques) to but not through bottom foil layer 306 (FIG. 3(b)).

Next a seed layer 312 is plated on foil layer 304 and in vias 310 FIG. 3(c)). Then foil layer 304 is patterned to form conductive traces. At the same time, vias 310 are plated and filled with copper to form posts 314 (FIG. 3(d).

Next, seed layer 312 is removed by flash etching and a solder mask 316 is formed over copper layer 304 (FIG. 3(e)). Then foil layer 306 is removed by etching or mechanical means (FIG. 3(f)).

Finally, a portion 302′ of the bottom surface of dielectric 302 is removed, for example, by chemical etching, mechanical means, laser etching, or plasma etching, or any other equivalent process (FIG. 3 (g)). This results in copper posts sticking out of the bottom surface of substrate dielectric layer 302. This process produces excellent co-planarity of the copper posts. The exposed height of the copper posts is determined by the controlled etching of dielectric 302 and results in a uniform height of posts 314.

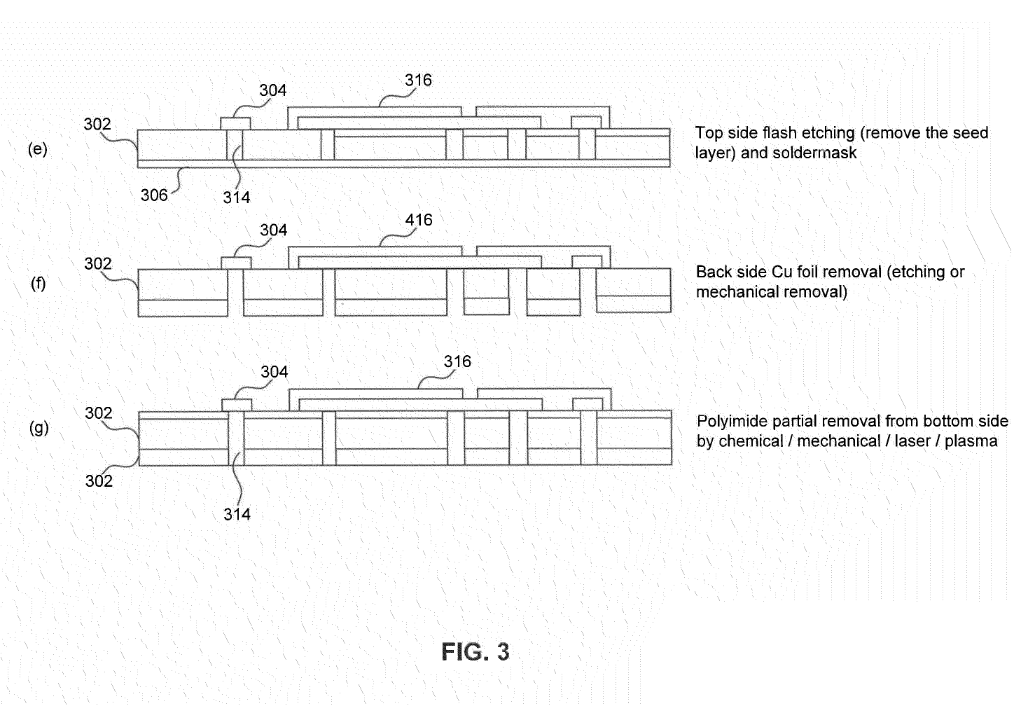

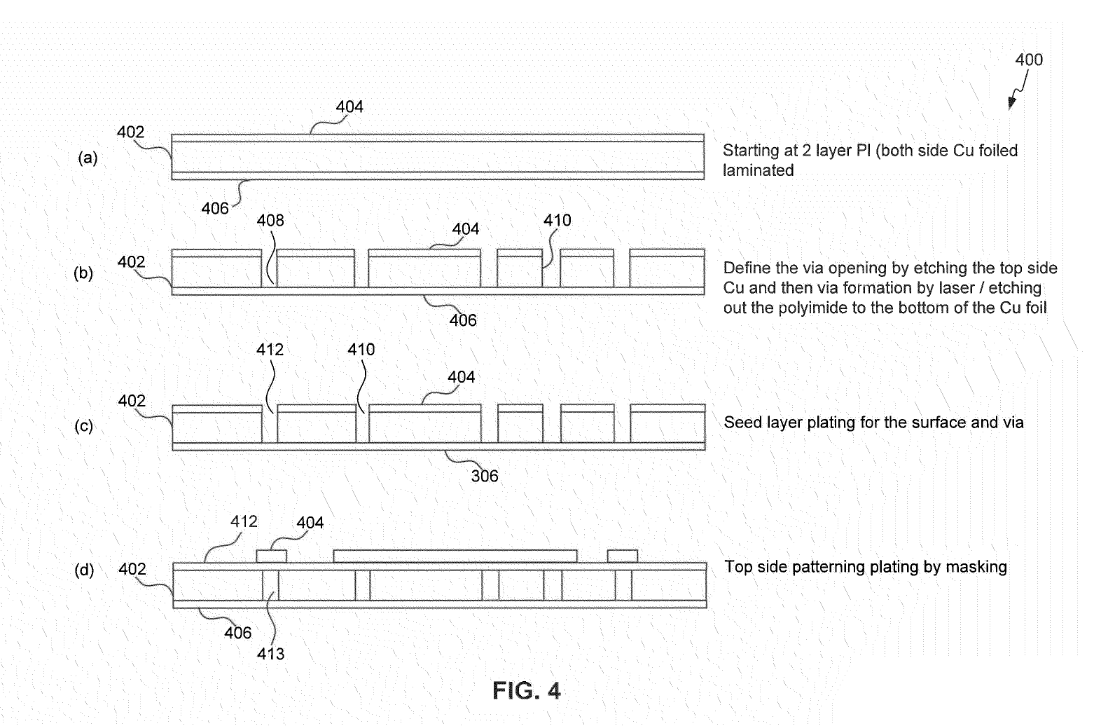

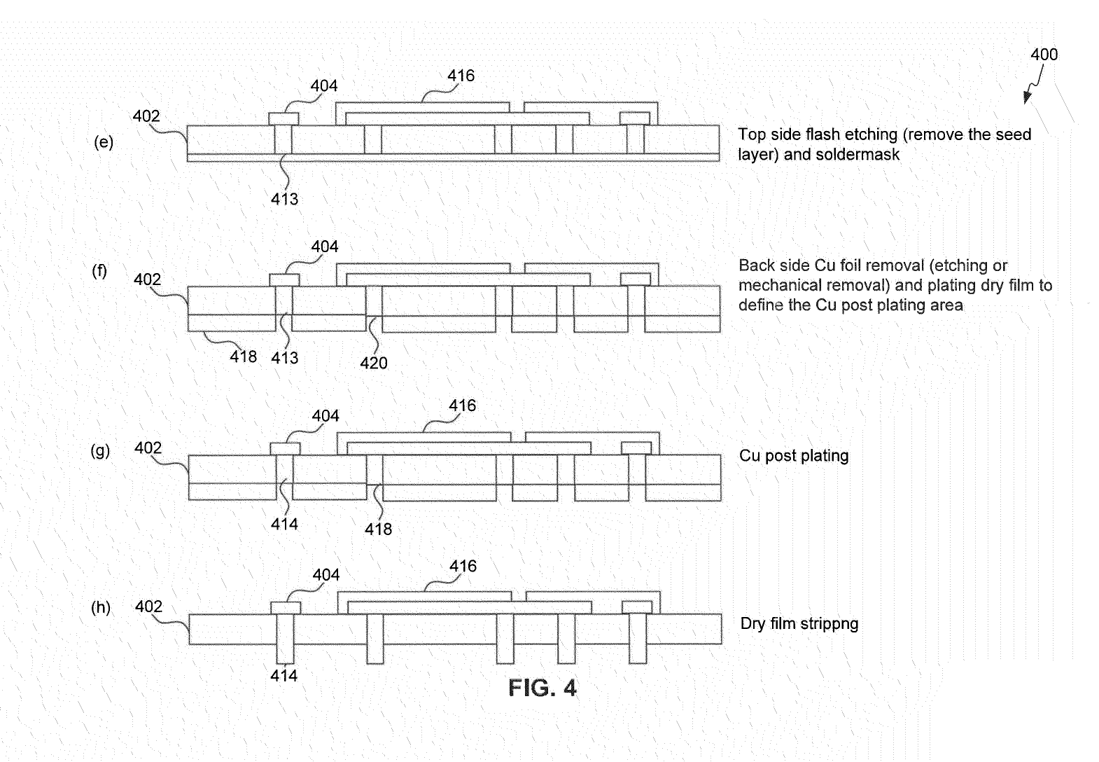

FIGS. 4(a)-(h) show a third embodiment incorporating features of the present invention. Steps 4(a)-4(d) are the same as steps 3(a)-3(d) for the second embodiment. Vias 410 are plated and filled with copper 413 down to bottom surface copper layer 406. A seed layer 412 which was formed at FIG. 4(c) is then removed by flash etching and a solder mask 416 is added to cover first copper layer 404 (FIG. 4(e).

Next, second foil layer 406 is removed by etching or mechanical means (FIG. 4(f). At this point the plated copper 413 in vias 410 is flush with the bottom surface of dielectric 402. A dry film plating mask 418 is then formed on the bottom surface of dielectric 402. Areas 420 coincident with vias 410 are left unmasked to define copper post plating areas.

Next, copper posts 414 are plated in the unmasked areas 420 of plating mask 418 (FIG. 4(f) as an extension of plated copper 413. In this embodiment, only a small amount of plating is needed to form posts 414. Typically, plating occurs only to the depth of plating mask 418 since vias 410 already contain copper plating from previous steps.

Finally, dry film plating mask 418 is stripped off by, for example, chemical etching, mechanical means, laser etching, or plasma etching, or any other equivalent process (FIG. 4(h)).

In this embodiment, coplanarity is relatively easy to control because less copper is being plated.

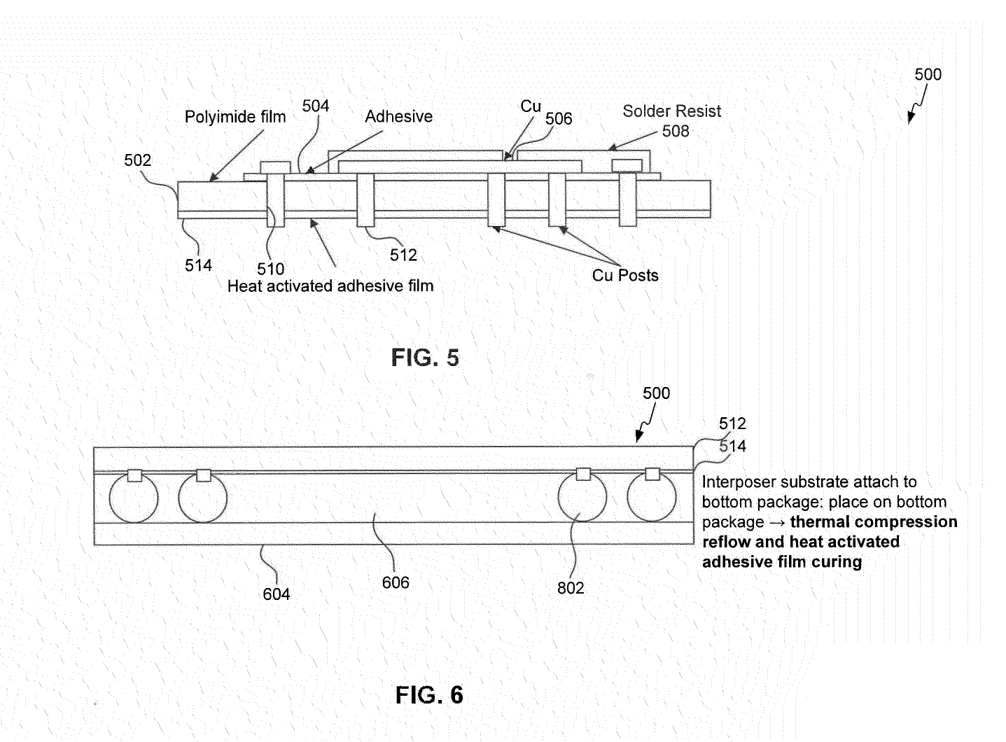

FIG. 5 shows an example of a finished PCB 500 manufactured according to any one of the embodiments described above. The PCB has a dielectric layer 502, which can be any of a number of materials. For example, if the PCB is to be flexible, dielectric 502 can be made of polyimide or any other suitable flexible material that would be known to one skilled in the relevant art. For a rigid PCB, dielectric 502 can be made of BT, FR-4, ceramic, glass, or other suitable material that would be known to one skilled in the relevant art. An adhesive layer is bonded to the top surface of 502. A laminated copper layer 504 is laminated or otherwise formed on top of adhesive layer 504 and is patterned into conductive traces. A solder mask 508 is applied over copper layer 506. Vias 510 extend from the top surface to the bottom surface of dielectric 502. Copper posts 512 are in electrical contact with copper layer 506 and extend through vias 510 to and protrude from the bottom surface of dielectric layer 502. An adhesive film 514 is formed on the bottom surface of dielectric 502. Copper posts 512 extend through adhesive film 514. Adhesive film 514 may be heat and/or pressure activated. Other types of thermoplastic and thermoset films may also be used. The material may be a polymer material or other type of adhesive that would be known to those skilled in the relevant art. In any event, the adhesive material should be non-conductive to prevent shorting between the electrical interconnects.

To form a complete package, PCB 500 is attached to a bottom package 600 as shown in FIG. 6. Copper posts 512 contact solder balls 602 formed on a package substrate 604. A mold compound 606 fills the spaces between solder balls 602. Adhesive film 514 contacts mold compound 606 to seal the space between PCB and bottom package 600. Without adhesive film 514, there would likely be gaps between the bottom surface of dielectric 502 and mold compound 606. Adhesive film 514 fills the gaps between the bottom of dielectric 502 and mold compound 606 and further protects the interconnection of copper posts 512 and contact pads (or solder balls) 602.

In one example, PCB 500 is mounted to bottom package 600 by laminating PCB 500 to bottom package 600. If adhesive film 514 is pressure and heat activated, it can be cured by pressure and/or temperature. Once PCB 500 is mounted to bottom package 600, the parts can be heated and/or pressed together to ensure adhesive layer 514 makes good contact with mold compound 606 and is properly cured.

FIG. 7 shows a cross-sectional view of a conductive metal post in situ. The post extends from the conductive layer on one surface of the dielectric through a via extending through the dielectric, and extends outwardly of the second surface of the dielectric from the via. It will be noted that the post portion extending outwardly of the second surface of the dielectric is typically of a smaller diameter than the portion of the conductive metal in the via. This is due to the slight misalignment of the holes in plating mask 214 with via holes 206, and their equivalents in the other embodiments described herein.

### CONCLUSION

While various embodiments of the present invention have been described above, it should be understood that they have been presented by way of example only, and not limitation. It will be apparent to persons skilled in the relevant art that various changes in form and detail can be made therein without departing from the spirit and scope of the invention. Thus, the breadth and scope of the present invention should not be limited by any of the above-described exemplary embodiments, but should be defined only in accordance with the following claims and their equivalents.

What is claimed is:

1. A circuit board having a metal post formed therethrough, comprising:
a conductive metal layer formed on a first surface of a dielectric and defining a conductive trace on the first surface of the dielectric;
a via formed through the dielectric; and
a conductive metal disposed in the via and substantially filling the via, the conductive metal in the via making contact with the conductive metal layer on the first surface of the dielectric, the conductive metal in the via extending outwardly of a second surface of the dielectric opposite the first surface to form a conductive post.

2. The circuit board of claim 1, further comprising:
a plurality of vias extending through the dielectric from the first surface to the second surface; and
a plurality of conductive posts disposed in the respective plurality of vias and extending outwardly of the second surface of the dielectric, wherein
the conductive metal layer defines a plurality of conductive traces on the first surface of the dielectric; and
the plurality of conductive posts make contact with respective ones of the plurality of conductive traces.

3. The circuit board of claim 2, further comprising:
an adhesive layer disposed between the plurality of conductive traces and the first surface of the dielectric.

4. The circuit board of claim 2, further comprising:
a seed layer temporarily formed on the second surface of the dielectric and extending into the plurality of vias before the plurality of conductive posts are disposed in the plurality of vias; wherein
the seed layer is removed after the conductive posts are disposed in the plurality of vias.

5. The circuit board of claim 1, further comprising:
an adhesive layer between the conductive metal layer and the first surface of the dielectric.

6. A printed circuit board, comprising:
a dielectric having first and second opposed surfaces;
a conductive metal layer formed on the first surface of the dielectric and defining conductive traces on the first surface of the dielectric;
a plurality of vias extending through the dielectric from the first surface thereof to the second surface of the dielectric; and
a conductive metal post formed in the each of the vias and in contact at one end portion thereof with at least a portion of the conductive traces and extending at the other end portion outwardly of the second surface of the dielectric.

7. The printed circuit board of claim 6, further comprising:
an adhesive film formed on the second surface of the dielectric for mating with a mold compound of a second dielectric assembly to provide a secure sealed contact with the second dielectric assembly.

8. The printed circuit board of claim 7, further comprising:
a solder mask formed over the conductive metal layer on the first surface of the dielectric.

9. A method of manufacturing a printed circuit board, comprising:
(a) forming a conductive metal layer on a first surface of a dielectric substrate;
(b) forming a via through the substrate;
(c) patterning the conductive metal layer to form a conductive trace on the first surface of the substrate;
(d) forming a plating mask on the second surface of the substrate;
(e) forming an opening in the plating mask that corresponds to the location of the via;
(f) depositing conductive metal in the via sufficient to substantially fill the via and make contact with the conductive metal layer on the first surface and substantially to the level of the plating mask; and
(g) removing the plating mask from the substrate such that a conductive post extends outwardly from the second surface of the substrate.

10. The method of claim 9, further comprising:
(h) forming a conductive seed layer on a second surface of the substrate opposite the first surface and in the via prior to step (d); and
(i) removing the seed layer from the second surface of the substrate after step (g).

11. The method of claim 9, further comprising:
(h) applying a solder mask over the conductive traces on the first surface of the substrate.

12. The method of claim 3, wherein step (h) is performed before step (d).

13. The method of claim 8, wherein step (h) is performed after step (g).

14. The method of claim 13, wherein step (c) is performed after step (g) and before step (h).

15. The method of claim 9, further comprising:
(h) forming an adhesive layer on the first surface of the substrate before step (a).

16. The method of claim 15, further comprising laminating the conductive metal layer to the adhesive layer.

17. A method of manufacturing a printed circuit board, comprising;
(a) forming a first conductive metal layer on a first surface of a dielectric substrate;
(b) forming a second conductive metal layer on a second surface of the dielectric substrate opposite the first surface;
(c) forming a via through the first conductive metal later and the substrate to but not through the second conductive metal layer;
(d) forming a conductive seed layer on the first conductive metal layer and in the via;
(e) depositing conductive metal in the via to the second conductive metal layer sufficient to substantially fill the via and make contact with the conductive metal layer on the first surface;
(f) removing the second conductive metal layer from the second surface of the substrate; and
(g) removing a portion of the second surface of the dielectric substrate to a depth sufficient such that a conductive post extends outwardly from the second surface of the substrate.

18. The method of claim 17, further comprising:
(h) patterning the first conductive layer to form conductive traces.

19. The method of claim 18, further comprising:
(i) forming a solder mask over the first conductive metal layer after step (e);
(j) removing the conductive seed layer after step (h); and
(k) removing the second conductive metal layer after step (h).

20. The method of claim 19, wherein step (h) is performed before step (i).

21. A method of manufacturing a printed circuit board, comprising:
(a) forming a first conductive metal layer on a first surface of a dielectric substrate;
(b) forming a second conductive metal layer on a second surface of the dielectric substrate opposite the first surface;
(c) forming a via through the first conductive metal later and the substrate to but not through the second conductive metal layer;
(d) forming a conductive seed layer on the first conductive metal layer and in the via;
(e) depositing conductive metal in the via to the second conductive metal layer sufficient to substantially fill the via and make contact with the conductive metal layer on the first surface;
(f) removing the second conductive metal layer from the second surface of the dielectric substrate;
(g) forming a plating mask on the second surface of the substrate;
(h) forming an opening in the plating mask that coincide with conductive metal deposit in the via;
(i) depositing conductive metal in the opening in the plating mask to electrically mate with the conducting metal deposit in the via; and
(j) removing the plating mask.

22. The method of claim 21, further comprising:
(k) patterning the first conductive layer to form conductive traces.

23. The method of claim 22, further comprising:
(l) forming a solder mask over the first conductive metal layer after step (e);
(m) removing the conductive seed layer after step (k); and
(n) removing the second conductive metal layer after step (l).

24. The method of claim 23, wherein step (k) is performed before step (l).
